(19) United States
(12) Patent Application Publication
(10) Pub. No.: US 2008/0229178 A1
(43) Pub. Date: Sep. 18, 2008

(54) Radio tag communication apparatus

(76) Inventor: Takahiro Shimura, Gotemba-shi (JP)

Correspondence Address: HARNESS, DICKEY & PIERCE, P.L.C., P.O. BOX 828, BLOOMFIELD HILLS, MI, 48303, US

(21) Appl. No.: 12/075,783

(22) Filed: Mar. 13, 2008

(30) Foreign Application Priority Data
Mar. 14, 2007 (JP) 2007-065351

(51) Int. Cl. H03M 13/03

(52) U.S. Cl. 714/789

(57) ABSTRACT

A signal transmitted from a radio tag is received, and an I-signal and a Q-signal are generated from the received signal. The I-signal and Q-signal are decoded, and a decoding error of the decoded data to be detected is detected and a decoded data error of the decoded data is detected based on an error detection code included in the decoded data to be detected. When no error more than a predetermined level exists in the detection results, the decoded data is stored as normal decoded data.

### CROSS-REFERENCE TO RELATED APPLICATIONS

This application is based upon and claims the benefit of priority from prior Japanese Patent Application No. 2007-065351, filed Mar. 14, 2007, the entire contents of which are incorporated herein by reference.

### BACKGROUND OF THE INVENTION

1. Field of the Invention

The present invention relates to a radio tag communication apparatus which receives and demodulates a signal transmitted from a radio tag.

2. Description of the Related Art

A radio tag communication apparatus (referred to as radio ID tag communication apparatus, in some cases), which wirelessly communicates with a radio tag such as a radio frequency identification (RFID) tag, transmits information to a radio tag using a modulated radio signal, and continues to transmit an unmodulated signal after the transmission of the information is terminated. To meet this, the radio tag executes back-scatter modulation by changing an amount of reflection of the unmodulated signal from the radio tag communication apparatus so as to transmit information to the radio tag communication apparatus. Then, the radio tag communication apparatus receives a back-scatter modulated wave to read information of the radio tag.

The radio tag communication apparatus includes a transmitting unit, a receiving unit and an antenna. The transmitting unit modulates a signal by a modulator, and amplifies the modulated signal by an amplifier to transmit the signal from the antenna. The receiving unit has a direct conversion receiver, and fetches a baseband signal from a high-frequency signal received by the antenna and decodes the baseband signal to extract information.

A direct conversion orthogonal demodulator inputs a local signal having the same frequency as a carrier of a received signal and the received signal into a mixer so as to produce an I (in-phase) signal of baseband, and then inputs a signal produced by shifting the phase of the local signal and the received signal into the mixer so as to produce a Q (quadrature phase) signal of the baseband.

Amplitudes of the I-signal and the Q-signal are determined by a phase difference between the received signal and the local signal. When the amplitude of the I-signal becomes maximum, the amplitude of the Q-signal becomes minimum, and when the amplitude of the I-signal becomes minimum, the amplitude of the Q-signal becomes maximum. When the amplitude of the Q-signal is minimum, i.e., zero, the amplitude of the I-signal is maximum, so that the received data can be reproduced by using the I-signal. Conversely when the amplitude of the I-signal is 0 as minimum, the amplitude of the Q-signal is maximum, so that the received data can be reproduced by using the Q-signal. In some cases, the phases of the I-signal and Q-signal may be inverted depending on the phase difference between the received signal and the local signal.

As a method for reproducing received data using a direct conversion orthogonal demodulator, a method for comparing amplitudes of an I-signal and a Q-signal and selecting a signal having a larger amplitude to reproduce received data has been known (for example, U.S. Pat. No. 6,501,807B1).

On the other hand, in case of RFID communication, response data of a radio tag is FM0 coded under the GEN2 standard of the EPC global, and the radio tag communication apparatus FM0 decodes the received response data of the radio tag. At this time, to detect a data error in decoded data, a 16-bit error detection code, that is, a cyclic redundancy check 16 (CRC16), is contained at an end of the response data of the radio tag. After receiving the response data from the radio tag, the radio tag communication apparatus recalculates CRC16 contained in the response data so as to detect a data error of the decoded data, that is, a CRC error. Unless the CRC error is detected, the reception data is output to an upper level host PC as normal data.

The radio tag communication apparatus may erroneously decode the response data of the radio tag and the CRC16 contained therein due to an influence of noise or the like. In this case, sometimes CRC check-sum meets accidentally, so that a radio tag having pseudo tag data which cannot exit in nature is detected.

Assume that real tag data is 128-bit “3000 3500 0000 0000 0002 54B3 2FF5 AF78 (HEX)”. 16-bit “AF78 (HEX)” at the end of the tag data is CRC16 for CRC error detection.

When the radio tag communication apparatus receives the real tag data normally and a result of recalculation of the CRC16 meets the checksum “1D0F (HEX)”, no CRC error is detected. Thus, the real tag data is regarded as normal tag data. If the tag data is received abnormally due to an influence of noise or the like in a communication passage between the radio tag and the radio tag communication apparatus and the result of recalculation of the CRC16 does not meet the checksum “1D0F (HEX)”, it is recognized as a CRC error. However, there is a possibility that the pseudo tag data meets the CRC16 with probability 1/65536 because the CRC16 is of 16-bits.

For example, assume that pseudo tag data “3000 3500 0202 0008 0202 54B3 2FF5 AF78 (HEX)” is received abnormally due to an influence of noise or the like. If the CRC16 of this tag data is recalculated, the result of calculation meets the checksum “1D0F (HEX)”, no CRC error is detected. Consequently, the tag data is recognized as normal tag data although it is pseudo tag data, with the result that it is output to an upper level host PC as normal data, which is a problem to be solved.

### BRIEF SUMMARY OF THE INVENTION

An object of one aspect of the present invention is to provide a radio tag communication apparatus excellent in reliability which can reduce the probability of fetching erroneous data due to an influence of noise or the like.

A radio tag communication apparatus according to one aspect of the invention comprises:

receiving means for receiving a signal transmitted from a radio tag, generating an I-signal from the received signal and a local signal having the same frequency as a carrier of the received signal, and generating a Q-signal from the received signal and a signal shifted by 90° in phase from the local signal;

decoding/error detection means for decoding a plurality of signals relevance to the I-signal and Q-signal generated by the receiving means, detecting a decoding error of each decoded data to be decoded, and detecting a decoded data error of each decoded data using an error detection code included in said each decoded data to be decoded; and

storage means for, when no more error than a predetermined level exists in the detection result of the decoding error and the detection result of the decoded data error, storing said each decoded data to be decoded as normal decoded data.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing a configuration of each embodiment;

FIG. 2 is a diagram showing a signal waveform of each unit of a digital signal processing unit according to each embodiment;

FIG. 3 is a diagram for explaining a method for creating other thresholds upon reproduction of received data according to each embodiment;

FIG. 4 is a diagram for explaining detection of sampling in each embodiment;

FIG. 5 is a flowchart for explaining the processing of an I-signal demodulating unit according to a first embodiment;

FIG. 6 is a flowchart for explaining decoding and decoding error check in each embodiment;

FIG. 7 is a diagram showing an output waveform of a binarizing unit in each embodiment;

FIG. 8 is a flowchart for explaining processing of an I-signal decoding unit and control of a control unit according to a second embodiment; and

FIG. 9 is a flowchart for explaining the processing of the I-signal decoding unit and the control of the control unit according to the second embodiment.

### DETAILED DESCRIPTION OF THE INVENTION

[1] Hereinafter, a first embodiment of the present invention will be described with reference to the accompanying drawings.

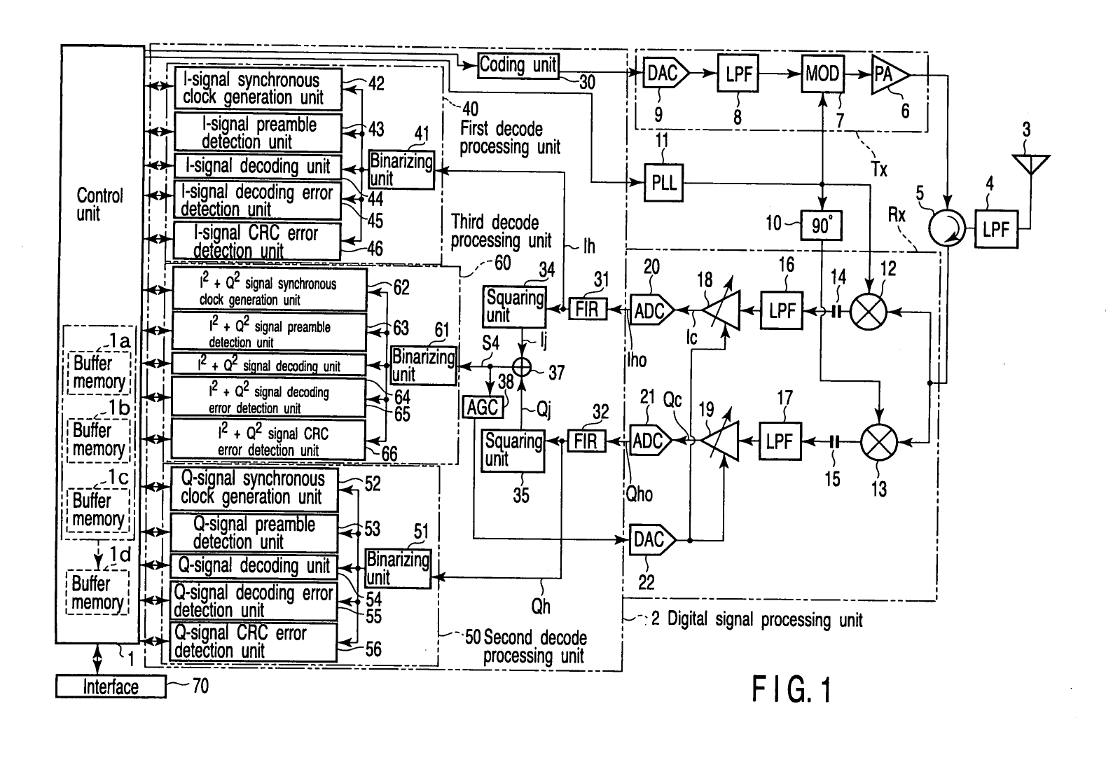

FIG. 1 shows a configuration of a radio ID tag communication apparatus including an orthogonal decoder. An orthogonal demodulator includes a control unit 1 for controlling the entire apparatus, a digital signal processing unit 2 which exchanges various kinds of digital data with the control unit 1, a transmitting unit TX for generating a radio wave to be transmitted, a receiving unit (receiving means) RX for processing the received radio wave, and an interface 70 for connection to an external device such as upper level host PC. The orthogonal demodulator includes an antenna 3 for radiating an electric wave outside, a low-pass filter (LPF) 4 which is connected to the antenna 3, a directional coupler 5 such as a circulator which is connected to the LPF while connected to the transmitting unit TX and receiving unit RX, a phase-locked loop (PLL) 11 which outputs a local signal having the same frequency as a carrier of a signal transmitted from the radio tag, and a phase shifter 10 for shifting the phase of the signal output from the PLL by 90°.

The control unit 1 includes a buffer memory 1a corresponding to a first decode processing unit 40 described later, a buffer memory 1b corresponding to a second decode processing unit 50 described later, a buffer memory 1c corresponding to a third decode processing unit 60 described later, and a buffer memory 1d for output.

The control unit 1 includes CPU, a ROM which includes preliminarily stored programs, and a RAM which stores data temporarily, and part of the RAM is allocated to the buffer memories 1a, 1b, 1c and 1d. The control unit 1 operates following a program so as to input and output transmitted/received data to and from the digital signal processing unit 2 for data communication with a radio tag (radio ID tag) (not shown). The control unit 1 causes the PLL 11 to output a local signal having the same frequency as a carrier of a signal transmitted from the radio tag.

The transmitting unit TX includes a power amplifier (PA) 6 which is connected to the directional coupler 5, a modulator (MOD) 7, a low-pass filter (LPF) 8 and a digital-to-analog converter (DAC) 9.

The receiving unit RX includes mixers 12 and 13, DC cut capacitors 14 and 15, low-pass filters (LPF) 16 and 17, variable-gain amplifiers 18 and 19, and analog-to-digital converters (ADCS) 20, 21 and 22.

The digital signal processing unit 2 has a coding unit 30 which codes a transmission signal output from the control unit 1 to the DAC 9 with, for example, a PIE code. The digital signal processing unit 2 includes finite impulse responses (FIR) 31 and 32 which respectively receive digital signals from the ADCs 20 and 21, squaring units 34 and 35, an adder (addition unit) 37, an automatic gain control (AGC) 38, a first decode processing unit 40, a second decode processing unit 50, and a third decode processing unit 60.

The first decode processing unit 40 has a binarizing unit 41 which binarizes an I-signal Ih supplied from the digital filter 31. The first decode processing unit 40 also includes an I-signal synchronous clock generation unit 42 to which the I-signal binarized by the binarizing unit 41 is supplied, an I-signal preamble detection unit 43, an I-signal decoding unit (first decoding means) 44, an I-signal decoding error detection unit (first decoding error detection means) 45, and an I-signal CRC error detection unit (first data error detection means) 46.

The second decode processing unit 50 has a binarizing unit 51 which binarizes a Q-signal Qh supplied from the digital filter 32. The second decode processing unit 50 also includes a Q-signal synchronous clock generation unit 52 to which the Q-signal binarized by the binarizing unit 51 is supplied, a Q-signal preamble detection unit 53, a Q-signal decoding unit (second decoding means) 54, a Q-signal decoding error detection unit (second decoding error detection means) 55, and a Q-signal CRC error detection unit (second data error detection means) 56.

The third decode processing unit 60 has a binarizing unit 61 which binarizes a (I²+Q²) signal S4 supplied from the adder 37. The third decode processing unit 60 also includes a (I²+Q²) signal synchronous clock generation unit 62 to which the (I²+Q²) signal binarized by the binarizing unit 61 is supplied, a (I²+Q²) signal preamble detection unit 63, a (I²+Q²) signal decoding unit (third decoding means) 64, a (I²+Q²) signal decoding error detection unit (third decoding error detection means) 65, and a (I²+Q²) signal CRC error detection unit (third data error detection means) 66.

The transmission signal coded by the coding unit 30 is digital-to-analog converted by the DAC 9 and supplied to the MOD 7 through the LPF 8. The MOD 7 modulates the amplitude of a local signal of the PLL 11 according to the transmission signal. The transmission signal obtained by the amplitude modulation is amplified in power by the PA 6, supplied to the antenna 3 through the directional coupler 5 and the LPF 4, and radiated from the antenna 3 as an electric wave.

A signal transmitted from the radio tag is received by the antenna 3, and that received signal is supplied to the mixers 12 and 13 through the LPF 4 and the directional coupler 5, respectively. Then, the local signal of the PLL portion 11 is supplied to the one mixer 12. The local signal of the PLL 11 is supplied to the other mixer 13 through the 90° phase shifter 10. The 90° phase shifter 10 outputs a signal shifted by 90° from the local signal. The mixer 12 mixes the received signal with the local signal to generate an I-signal having the same phase component as the local signal. The mixer 13 mixes the received signal with the local signal shifted by 90° to generate a Q-signal which is an orthogonal component of the local signal.

The I-signal generated by the mixer 12 is deprived of a DC component by the DC cut capacitor 14 and further deprived of an unnecessary high-frequency component by the LPF 16. Then, the I-signal is amplified to a predetermined magnitude by the variable-gain amplifier 18 to be an I-signal Ic. The I-signal Ic is converted to a digital I-signal Iho by the ADC 20 which digitizes a received signal (baseband signal). Then, the digital I-signal Iho is input to the digital signal processing unit 2.

The Q-signal generated by the mixer 13 is deprived of a DC component by the DC cut capacitor 15 and further deprived of an unnecessary high-frequency component by the LPF 17. Then, the Q-signal is amplified to a predetermined magnitude by the variable-gain amplifier 19 to be a Q-signal Qc. The Q-signal Qc is converted to a digital Q-signal Qho by the ADC 21 which digitizes a received signal (baseband signal). Then, the digital Q-signal Qho is input to the digital signal processing unit 2.

Consequently, direct conversion type receiving means is constituted of a system from the antenna 3 to the ADCs 20 and 21.

To securely take out data from the modulated received signal, a sampling time interval of the ADCs 20, 21 needs to be set to a shorter time than ½ the shortest time in which the level of the modulated received signal is not changed. The sampling time interval is set to ¼ the shortest time in which the level of the modulated received signal is not changed. In other words, it is set to a sampling frequency which is four times the minimum frequency at which the level of the modulated received signal is not changed.

The I-signal Iho digitized by the ADC 20 turns to an I-signal Ih whose band is limited by a digital filter of the digital signal processing unit 2, for example, the FIR 31. Likewise, the Q-signal Qho digitized by the ADC 21 turns to a Q-signal Qh whose band is limited by a digital filter of the digital signal processing unit 2, for example, the FIR 32.

The I-signal Ih whose band is limited is supplied to the first decode processing unit 40 and squared by the squaring unit 34 to be an I-signal Ij indicating its squared value I². The Q-signal Qh whose band is limited is supplied to the second decode processing unit 50 and squared by the squaring unit 35 to be a Q-signal Qj indicating its squared value I². The I-signal Ij and Q-signal Qj are supplied to the adder 37. From the adder 37, output is a (I²+Q²) signal S4 based on summing the I-signal Ij (squared value I²) and the Q-signal Qj (squared value Q²). The (I²+Q²) signal S4 is supplied to the third decode processing unit 60 and supplied to the AGC 38. The AGC 38 controls an output voltage of the DAC 22 when the amplitude of the (I²+Q²) signal S4 output from the adder 37 is lower than a predetermined threshold, so as to raise gains of the variable-gain amplifiers 18, 19.

The processings of the first decode processing unit 40, the second decode processing unit 50 and the third decode processing unit 60 will be described.

In the first decode processing unit 40, the I-signal synchronous clock generation unit 42 generates a clock signal synchronous with the binarized signal from the binarizing unit 41 and supplies the generated clock signal to the I-signal preamble detection unit 43, the I-signal decoding unit 44, the I-signal decoding error detection unit 45 and the I-signal CRC error detection unit 46, respectively, through the control unit 1. The I-signal preamble detection unit 43 compares the I-signal with preliminarily set preamble pattern data synchronously with the clock signal generated by the I-signal synchronous clock generation unit 42, thereby to detect preamble data which is specified pattern data. The I-signal decoding unit 44, upon receiving a decoding start instruction from the control unit 1 accompanied by the detection of the preamble data, decodes the I-signal by FM0 decoding or Manchester decoding. Similarly, upon receiving a decoding start instruction from the control unit 1 accompanied by the detection of the preamble data, the I-signal decoding error detection unit 45 detects a decoding error of data decoded by the I-signal decoding unit 44 (FM0 decoding error check or Manchester decoding error check). The I-signal CRC error detection unit 46 uses the CRC16 of an error detection code included in data decoded by the I-signal decoding unit 44 so as to detect a data error of the decoded data or a CRC error.

The processing performed by the second decoded processing unit 50 is similar to that performed by the first processing unit 40 except that the signal to be processed is a Q-signal. Therefore, a description of the processing performed by the second decoded processing unit 50 will be omitted herein.

In the third decode processing unit 60, the (I²+Q²) signal synchronous clock generation unit 62 generates a clock signal synchronous with the binarized signal from the binarizing unit 61, and supplies the generated clock signal to the (I²+Q²) signal preamble detection unit 63, the (I²+Q²) signal decoding unit 64, the (I²+Q²) signal decoding error detection unit 65 and the (I²+Q²) signal CRC error detection unit 66 through the control unit 1. The (I²+Q²) signal preamble detection unit 63 compares the (I²+Q²) signal with preliminarily set preamble pattern data synchronously with the clock signal generated by the (I²+Q²) signal synchronous clock generation unit 62, thereby to detect preamble data which is specified pattern data. The (I²+Q²) signal decoding unit 64, upon receiving a decoding start instruction from the control unit 1 accompanied by the detection of the preamble data, decodes the (I²+Q²) signal by FM0 decoding or Manchester decoding. Similarly, upon receiving a decoding start instruction from the control unit 1 accompanied by the detection of the preamble data, the (I²+Q²) signal decoding error detection unit 65 detects a decoding error of decoded data to be decoded by the (I²+Q²) signal decoding unit 64 (FM0 decoding error check or Manchester decoding error check). The (I²+Q²) signal CRC error detection unit 66 uses the CRC16 of an error detection code contained in decoded data to be decoded by the (I²+Q²) signal decoding unit 64 so as to detect a data error of the decoded data or a CRC error.

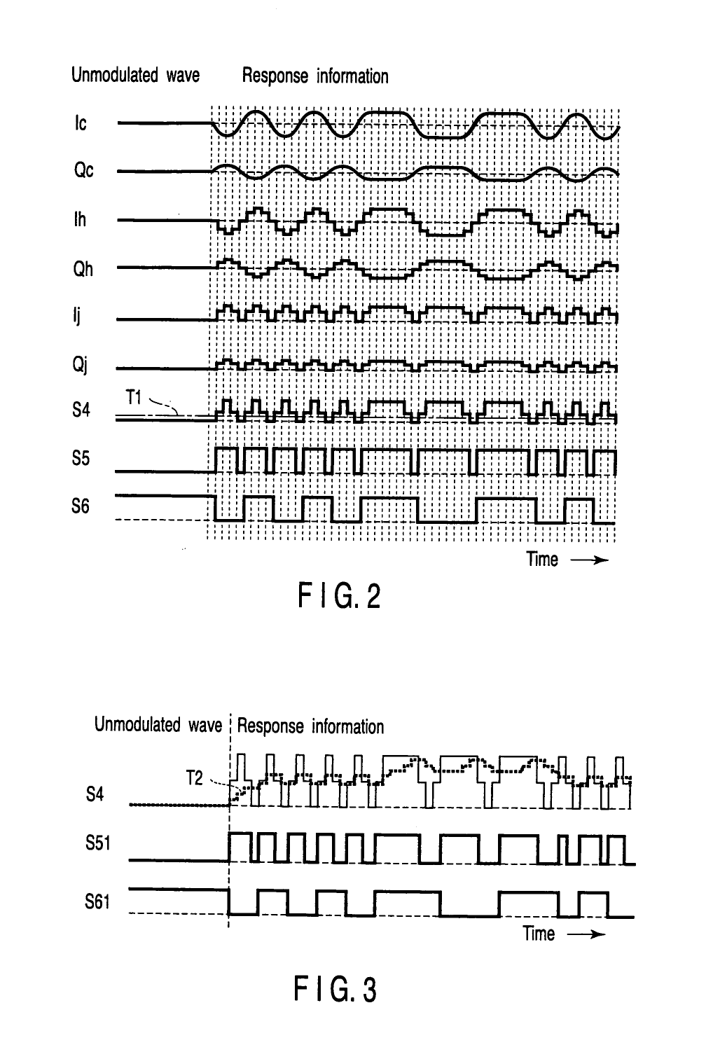

FIG. 2 shows an output waveform of each section upon reproducing the received data. The I-signal Ic output from the LPF 16 is sampled by the ADC 20 and digitized, and further band-limited by the digital filter 31 to be turned into the I-signal Ih. The Q-signal Qc output from the LPF 17 is sampled by the ADC 21 and digitized, and then band-limited by the digital filter 32 to be turned into the Q-signal Qh.

The I-signal Ih and Q-signal Qh are squared by the squaring units 34 and 35 to be converted to the I-signal Ij and the Q-signal Qj, respectively. Then, the I-signal Ij and the Q-signal Qj are summed by the adder 37 to generate the (I²+Q²) signal S4.

The binarizing unit 61 has a function of generating a signal which turns to high level only in a period when the (I²+Q²) signal S4 supplied from the adder 37 is a predetermined threshold or more, and generating binary data by inverting the signal level each time when the signal is raised so as to binarize the (I²+Q²) signal S4 at a threshold T1. That is, when the signal is the threshold T1 or less the binarizing unit 61 creates a signal S5 at low level and when the signal is above the threshold T1 the binarizing unit 61 creates a signal S5 at high level, respectively, and further inverts the signal level when the signal S5 rises to generate a signal S6. Consequently, the decoded data signal S6 of the received signal received by the antenna 2 is obtained.

When the amplitude of the (I²+Q²) signal S4 supplied from the adder 37 is lower than the threshold T1, the AGC 38 controls an output voltage of the DAC 22 so that the gain of each of the variable-gain amplifiers 18, 19 is raised. Further, if there is no period in which the amplitude of the (I²+Q²) signal S4 is on a lower level than the threshold T1, the AGC 38 controls the output voltage of the DAC 22 so that the gain of each of the variable-gain amplifiers 18, 19 is lowered. A redeive signal strength indicator (RSSI) value of the received signal is acquired from the amplification factor of the variable-gain amplifiers 18, 19 and the amplitude of the (I²+Q²) signal S4 and consequently, the control unit 1 executes carrier sense. An orthogonal demodulator for reproducing received data from the received signal can be configured by digital processing with the squaring units 34, 35, the adder 37 and the binarizing unit 61, so that influences of noise can be suppressed as much as possible even if the level of the received signal is reduced, whereby the received data can be decoded securely.

Although a processing of creating the binary signal S5 from the (I²+Q²) signal S4 and generating the decoded data signal S6 from the signal S5 is carried out, the present invention is not restricted to this example. It is permissible to generate the decoded data signal S6 by executing a processing of inverting the signal level when the (I²+Q²) signal S4 rises to more than the threshold T1 from not higher than the threshold T1. Although the sampling frequency of the ADCs 20, 21 is set to four times the minimum frequency in which the level of the modulated received signal does not change, a difference in frequency between the frequency component of the modulated received signal and the sampling frequency can be increased by increasing the sampling frequency. This advantageously facilitates the configuration of an anti-aliasing filter. Further, although the (I²+Q²) signal S4 is produced by binarization using the preliminarily set threshold T1, the present invention is not restricted to this example. It may be produced using data before a time when the threshold T1 is binarized. As shown in FIG. 3, the (I²+Q²) signal S4 may be binarized using the threshold T2 produced from an average of six sampling data continuous from data five sampling data before the binarization time up to sampling data to be binarized. Because the average is gained from the six sampling data, that is, an average in terms of time is obtained, a sudden time change cannot be met, but a change in DC level can be met. Consequently, the threshold T2 is changed depending on the value of the (I²+Q²) signal S4 which is changed with a passage of time. Then, the (I²+Q²) signal S4 is binarized based on the threshold T2. That is, when the (I²+Q²) signal S4 is the threshold T2 or less it is binarized at low level and when the (I²+Q²) signal S4 is above the threshold T2 it is binarized at high level, and high levels, respectively, so as to produce the signal S51 shown in FIG. 3. Then, the decoded data signal S61 is generated by inverting the signal level when the signal S51 rises. As a result, the decoded data signal S61 of the back scatter signal received by the antenna 2 can be obtained. In the meantime, the number of continuous samplings for calculating the average needs to be over a sampling number by which the value sampled by the ADCs 20, 21 continuously marks a maximum value plus 1. Then, by increasing the sampling number for calculating the average as more as possible, a level fluctuation of the threshold T2 can be reduced.

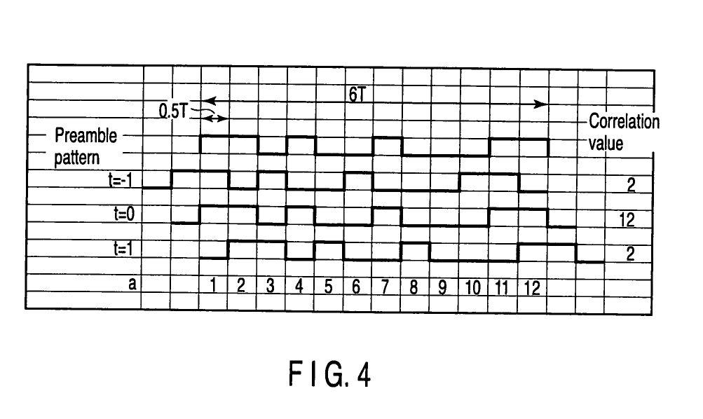

Upon receipt of a preliminarily determined data quantity from the decoding units 40, 50, 60, the control unit 1 sends an instruction to the CRC error detection units 46, 56, 66 so as to obtain data error detection results from the CRC error detection units 46, 56, 66 and confirm whether or not there is any data error. Detection of the preamble by the preamble detection units 43, 53, 63 is carried out as shown in FIG. 4. For example, preamble pattern data which is changed every 0.5 T is set in advance to a cycle T corresponding to a transmission speed. Time shifted by 0.5 T from time t=−1 is indicated as t=0, and time shifted by 0.5 T is indicated as t=1. For each pattern data, a correlation value is calculated with high level of 1 and low level of −1.

Assuming that the preamble pattern data is f(a), an input signal is r(a) and “a” is a natural number of 1 to 12, a correlation value c is expressed in the following equation.

$$C = \vert {\sum }_{a = 1}^{12} ( f ( a ) \times r ( a ) ) \vert$$

As evident from FIG. 4, the correlation value c indicates a large value when the patterns coincide. Even if part of data is erroneous, pattern coincidence can be detected if the correlation value is larger than a specified level. If the threshold of the correlation value c is set to, for example, 10, it is determined that the preamble is detected when the correlation value c is 10 or more.

To communicate with the radio ID tag in this configuration, first, an unmodulated carrier is transmitted to the radio ID tag to supply power to the radio ID tag. More specifically, the output of the coding unit 30 is set to high level, and a local signal generated by the PLL 11 is supplied to the MOD (modulator) 7 to set the amplitude of the MOD 7 to a maximum level. Then, a signal from the MOD 7 is amplified by the power amplifier (PA) 6 and supplied to the directional coupler 5. After an unnecessary high-frequency component is removed by passing a signal from the directional coupler 5 through the LPF 4, the unmodulated carrier is transmitted to the radio ID tag from the antenna 3.

To transmit data to the radio tag, the transmitting data is transmitted from the control unit 1 to the coding unit 30 with the local signal generated by the PLL 11 being supplied to the MOD 7. Thus, the transmitting data is coded by the coding unit 30 with, for example, a PIE code, and the coded data is converted to an analog signal by the DAC 9, input to the MOD 7 through the LPF 8 and modulated in amplitude using the local signal. The signal modulated in amplitude is wirelessly transmitted from the antenna 3 to the radio tag through the PA 6, the directional coupler 5 and the LPF 4.

After the radio tag finishes receiving data from the apparatus, the radio tag modulates the amplitude by back scatter when transmitting the unmodulated wave from the apparatus, so as to transmit a signal comprised of a synchronous portion composed of bit synchronism or preamble, a data portion and a CRC bit portion following the synchronous portion as a response signal.

The apparatus receives a response signal from the radio tag through the antenna 3. When receiving the response signal, an unnecessary high-frequency component is removed by the LPF 4 and the signal is input to the mixers 12, 13 through the directional coupler 5. The mixer 12, using the local signal from the PLL 11, generates the I-signal having the same phase component as the carrier signal. The mixer 13 generates the Q-signal which is an orthogonal component to the carrier signal using the local signal shifted by 90° by the 90° phase shifter 10.

After the I-signal from the mixer 12 turns to a coded data component after removal of the unnecessary high-frequency component by the LPF 16, the I-signal is amplified by the variable-gain amplifier 18 and digitized by the ADC 20. Then, the converted I-signal is input to the IQ-signal synthesizing unit including the squaring units 34, 35 and the adder 37 through the digital filter 31 while input to the first decode processing unit 40.

After the Q-signal from the mixer 13 turns to a coded data component after removal of the unnecessary high-frequency component by the LPF 13, the Q-signal is amplified by the variable-gain amplifier 19 and digitized by the ADC 21. Then, the converted Q-signal is input to the IQ-signal synthesizing unit including the squaring units 34, 35 and the adder 37 through the digital filter 32 while input to the first decode processing unit 50.

The I-signal and Q-signal input to the IQ-signal synthesizing unit are squared as described previously and summed by the adder 37, followed by being input to the third decode processing unit 60.

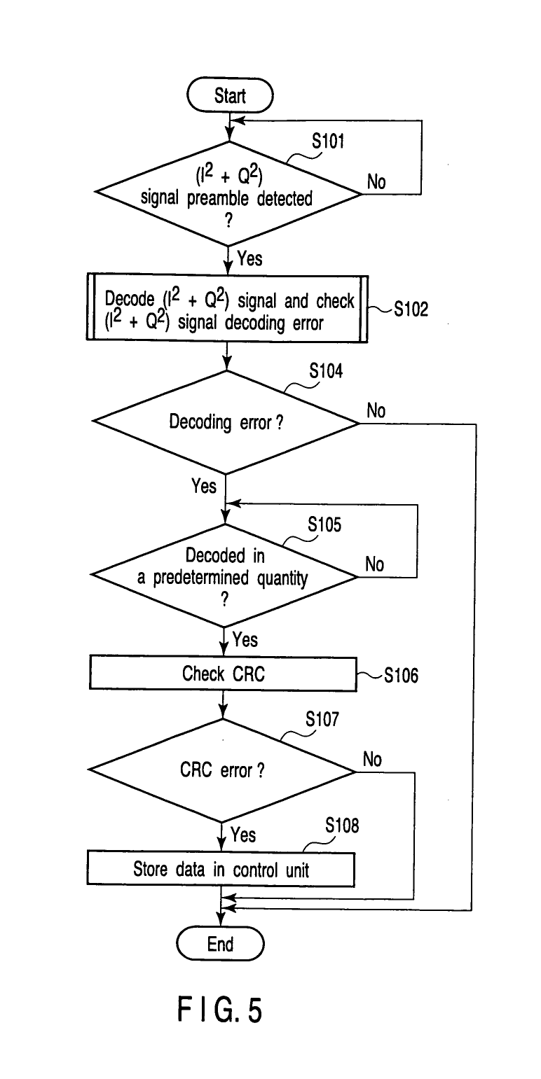

Reception of response data from the radio tag will be described with reference to FIG. 5. Because the same processing is carried out for the I-signal, Q-signal and (I²+Q²) signal, only the processing of the (I²+Q²) signal will be described, and thus, description of the decoding error check processing for the I-signal and Q-signal is omitted.

The control unit 1 determines whether or not a notice of detection of the preamble of the signal I from the (I²+Q²) signal preamble detection unit 63 is received (step 101: hereinafter abbreviated as S101). If it is determined that the notice of detection of the preamble of the signal I from the (I²+Q²) signal preamble detection unit 63 is received (YES in S101), the control unit 1 decodes the (I²+Q²) signal and executes the decoding error check processing for the (I²+Q²) signal (S102: decoding/error detection means). Description of the detail of this S102 will be described later. After the processing of S102 is terminated, the control unit 1 determines whether or not there is any decoding error in information decoded from the (I²+Q²) signal (S104). If it is determined that there is no decoding error (YES in S104), the control unit 1 determines whether or not the information decoded from the (I²+Q²) signal has been decoded in a predetermined data quantity (S105). If it is determined that they have been decoded in the predetermined data quantity (YES in S105), the control unit 1 dispatches an instruction to the (I²+Q²) signal CRC error detection unit 66 for executing the CRC error check to determine whether or not there is any data error, and receives the result (S106). The control unit 1 determines whether or not there is any CRC error (S107). If it is determined that there is no CRC error (YES in S107), the decoded data is stored in the buffer memory 1c as normal decoded data (S108: storage means). In case of processing the I-signal, the decoded data is stored in the buffer memory 1a as normal decoded data in S108, and in case of processing the Q-signal, the decoded data is stored in the buffer memory 1b as normal decoded data in S108. If it is determined that there is any CRC error in S107 (NO in S107), the processing of FIG. 5 is terminated. If it is determined that there is any decoding error in S104 (NO in S104), the processing of FIG. 5 is terminated.

Although not shown in the flowchart, one piece of the decoded data stored in the buffer memory 1a or 1c after the processing of FIG. 5 is terminated is transferred to the buffer memory 1d. At this time, decoded data having neither decoding error nor error detection error is transferred to the buffer memory 1d. The buffer memory 1d may be used as a storage means for storing the decoded data.

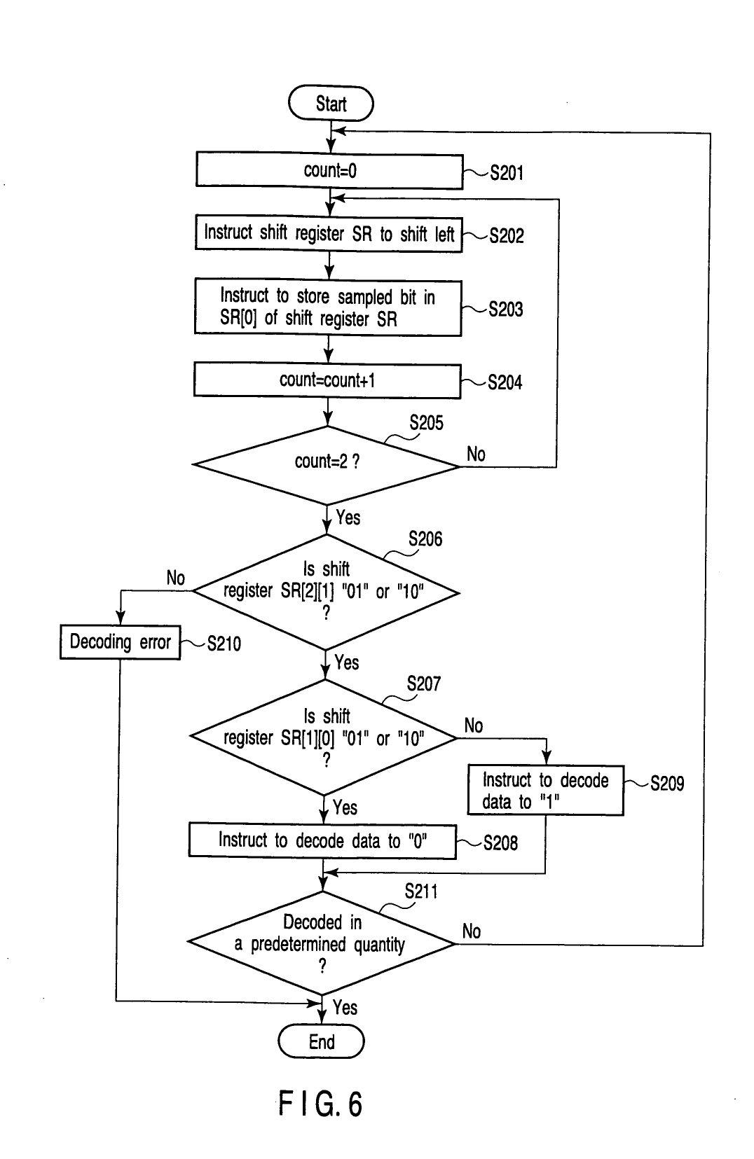

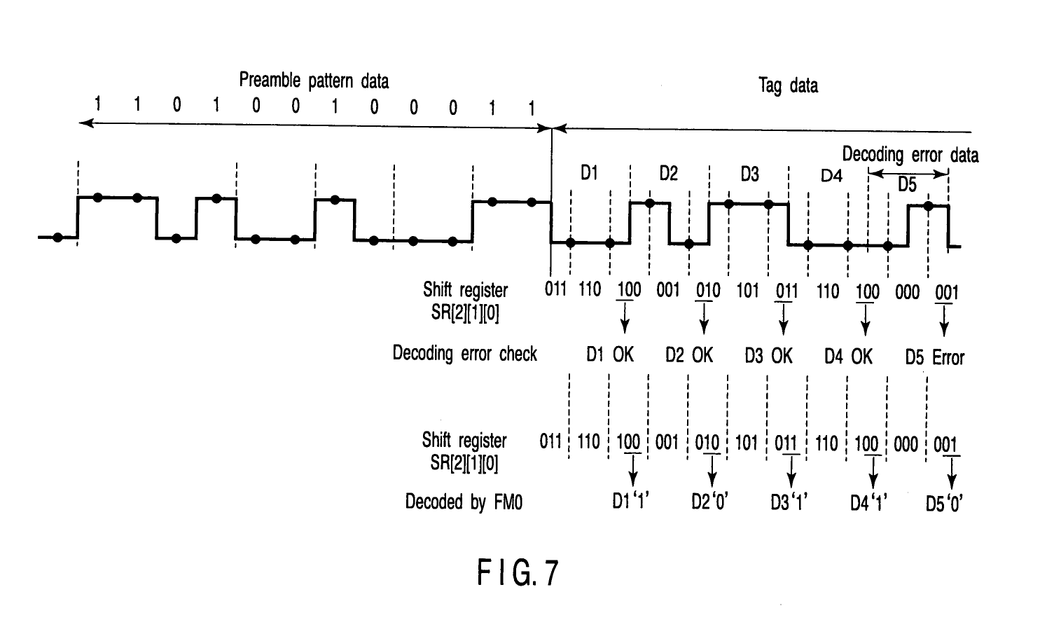

The decoding and decoding error check processing shown in S102 will be explained using FIGS. 6 and 7 about an example that the response data from the radio tag is coded by FM0. Because the same processing is carried out for the I-signal, the Q-signal and the (I²+Q²) signal, only the decoding error check for the (I²+Q²) signal will be described, and description of the decoding error check processing for the I-signal and Q-signal is omitted.

FIG. 7 shows an output waveform of the squaring unit 61 for squaring the (I²+Q²) signal, the preamble pattern data and following tag data. The response data from the radio tag is sampled twice its transmission speed by the synchronous clock, and the sampled data is fetched into, for example, a shift register SR of 12 bits successively. When the content of the 12-bit shift register meets the preamble pattern data of 12 bits, the preamble is detected by the control unit 1 and the following tag data is decoded by FM0.

FIG. 6 shows a flow of the FM0 decoding and FM0 decoding error check when the binarized (I²+Q²) signal is sampled twice the transmission speed. Due to the double sampling, one piece of data of FM0 is decoded by sampling data of 2 bits. First, the counter is initialized as 0 (count=0) (S201). An instruction for shifting the shift register SR leftward by 1 bit is dispatched to the third decode processing unit 60 (S202). An instruction for storing a sampled bit into the lowest bit (SR[1][0]) of the shift register SR is dispatched to the digital signal processing unit 2 (S203). The value of the counter is incremented by 1 (S204). Whether or not the counter value is “2” is determined (S205). If it is determined that the counter value is not “2” (NO in S205), the control unit 1 returns to S202. If it is determined that the counter value is “2” (YES in S205), the control unit 1 determines whether or not the value of SR[2][1] of the shift register SR is “01” or “10” (S206). If it is determined that the value of the SR[2][1] bit of the shift register SR is “01” or “10” (YES in S206), the control unit 1 determines whether or not the value of the SR[1][0] of the shift register SR is “01” or “10” (S207). If it is determined that the value of the SR[1][0] of the shift register SR is “01” or “10” (YES in S207), the control unit 1 instructs the digital signal processing unit 2 to decode data to “0” (S208). If it is determined that the value of the SR[1][0] bit of the shift register SR is “01” or “10” (NO in S207), the control unit 1 instructs the third decode processing unit 60 to decode data to “1” (S209). On the other hand, if it is determined that the value of the SR[2][1] bit of the shift register SR is not “01” or “10” (NO in S206), the control unit 1 processes decoding error (S210). If as shown in FIG. 7, bit inversion does not occur on a border between D4 and D5 due to an influence of noise or the like so that coding error of FM0 is generated, the value of the SR[2][1] bit of the shift register SR turns to “00” at D5, with the result that decoding error is detected. If decoding of data of 1 bit is terminated in S207 or S208, it is determined whether or not decoding of predetermined quantity of data is completed (S211). If it is determined that the decoding of the predetermined quantity of data is not completed (NO in S211), the control unit 1 returns to the processing of S201. If it is determined that decoding of the predetermined quantity of data is completed (YES in S211), the control unit 1 terminates the processing shown in FIG. 6. The flow of the FM0 decoding and FM0 decoding error check shown in FIG. 6 have been described as processing of the control unit 1. Alternatively, part or all of the processing shown in FIG. 6 may be executed by the (I²+Q²) signal decoding error detection unit 65 and the (I²+Q²) signal CRC error detection unit 66, and only a detection result may be returned to the control unit 1.

The shift register SR is provided at each of the first decode processing unit 40, the second decode processing unit 50 and the third decode processing unit 60.

Because decoding error check of each data is carried out together with the CRC error check as a set, it is possible to reduce a probability that a CRC error check having error data due to noise or the like may pass accidentally to transmit the erroneous tag data to the upper level host PC or the like.

That is, the probability of fetching erroneous data due to the influence of noise or the like can be reduced without inducing an increase in the size of a circuit on a radio tag and an accompanying rise in cost. Consequently, reliability of radio communication is improved.

If no decoding error or CRC error is detected in the first decode processing unit 40, the second decode processing unit 50 and the third decode processing unit 60 and plural data are acquired, it is permissible to preliminarily apply priority order to the I-signal decoding unit 44, the Q-signal decoding unit 54 and the (I²+Q²) signal decoding unit 64 and adopt data having the highest priority order and decoded from a signal including neither decoding error nor CRC error as normal decoded data by means of a storage means. In the first embodiment, the (I²+Q²) signal has the highest priority.

Theoretically, only the (I²+Q²) signal may be used for decoding because it includes information about both the I-signal and Q-signal. However, if the response data from the radio tag is weak because a distance between the radio tag and the radio tag communication apparatus is long, it is better, in some cases, to use the I-signal or the Q-signal independently rather than the (I²+Q²) signal. This is for the following reason. For example, when both the I-signal and the Q-signal have a small amplitude and the SN ratio of the I-signal is worse than the SN ratio of the Q-signal, the amount of information of the (I²+Q²) signal becomes smaller than the amount of information of the I-signal alone due to the worse SN ratio of the Q-signal.

The control unit 1 may be stores decoded data (any decoded data stored in the buffer memories 1a, 1b and 1c) having no decoding error in the detection results of the decoding error detection units 45, 55 and 65 as normal decoded data under a condition that all the detection results of the CRC error detection units 46, 56 and 66 are notices having no CRC error (no data error).

In this case, the detection result may be stored according to the priority order of the decoding units. 44, 54 and 64.

[2] A second embodiment will be described.

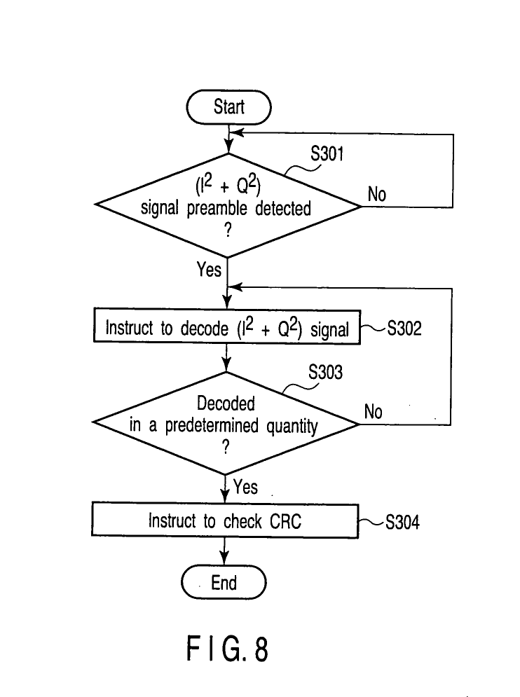

A different point from the first embodiment exists in handling of the decoded data in the control unit 1. The processing thereof is shown in the flowchart of FIG. 8 corresponding to FIG. 5 of the first embodiment. Because the same processing is carried out for any one of the I-signal, Q-signal and (I²+Q²) signal, the processing of only the (I²+Q²) signal will be described, and description of the decoding error check processing for the I-signal and Q-signal is omitted.

The control unit 1 determines whether or not the preamble of the signal I from the (I²+Q²) signal preamble detection unit 63 is received (step 301). If it is determined that notice of detection of the preamble of the signal I is received from the (I²+Q²) signal preamble detection unit 63 (YES in S301), the control unit 1 instructs to decode the (I²+Q²) signal (S302). Here, the decoding error check may be carried out like the first embodiment. Next, the control unit 1 determines whether or not the decoded data decoded from the (I²+Q²) signal has been decoded in a predetermined quantity (S303). If it is determined that they have not been decoded in the predetermined quantity (NO in S303), the control unit 1 returns to S302.

If it is determined that they have been decoded in the predetermined quantity (YES in S303), the control unit 1 instructs the (I²+Q²) signal CRC error detection unit 66 to perform the CRC error check for determining whether or not there is any data error (S304).

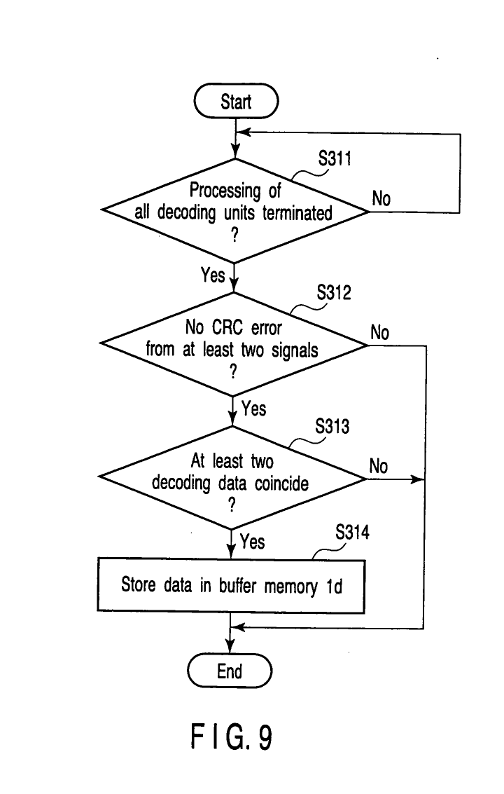

FIG. 9 shows processing after the processing shown in FIG. 8. It is determined whether or not the processing of S304 is terminated for all the I-signal, Q-signal and (I²+Q²) signal (S311). If it is determined that the processing for all the signals is terminated (YES in S311), it is determined whether or not the CRC error has been detected from at least two signals of the I-signal, Q-signal and (I²+Q²) signal (S312). If it is determined that plural CRC errors are detected (NO in S312), the control unit 1 terminates the processing of FIG. 9. If it is determined that no plural CRC errors are detected, that is, if there is one CRC error or no CRC error (YES in S312), the control unit 1 determines whether or not the plural decoded data coincide (S313). If it is determined that the plural decoded data coincide (YES in S313), the control unit 1 stores the decoded data having neither CRC error nor decoding error in the buffer memory 1d for output as normal decoded data (S314: storage means). If it is determined that no plural decoded data coincide in the processing of S313 (NO in S313), the processing of FIG. 9 is terminated as it is.

In conclusion, the detection result of each CRC error detection unit 46, 56, 66 has no plural CRC error (no data error). In this case, under a condition that plural detection results of the decoding error detection units 45, 55 and 65 have no decoding error and the respective decoded data having no decoding error coincide with one another, the control unit 1 stores the respective coinciding decoded data as the normal decoded data.

The other configuration, operation and effect of the third embodiment are the same as those in the first embodiment and thus, description thereof is omitted.

Although in the respective embodiments, three signals, the I-signal, Q-signal and (I²+Q²) signal are used as the plural signals including the I-signal and Q-signal, the number of signals for use is not restricted to three but may be of any number as long as plural signals are used. However, if only two signals, I-signal and Q-signal are provided, storing normal decoded data in a state in which an error is detected in part of the decoded data results in not so good accuracy. The number of signals for use is preferred to be three or more.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A radio tag communication apparatus comprising:
receiving means for receiving a signal transmitted from a radio tag, generating an I-signal from the received signal and a local signal having the same frequency as a carrier of the received signal, and generating a Q-signal from the received signal and a signal shifted by 90° in phase from the local signal;
decoding/error detection means for decoding a plurality of signals relevance to the I-signal and Q-signal generated by the receiving means, detecting a decoding error of each decoded data, and detecting a decoded data error of each decoded data using an error detection code included in said each decoded data; and
storage means for, when no more error than a predetermined level exists in the detection result of the decoding error and the detection result of the decoded data error, storing said each decoded data as normal decoded data.

2. The apparatus according to claim 1, wherein the decoding/error detection means includes:
first decoding means for decoding the I-signal;
second decoding means for decoding the Q-signal;
third decoding means for decoding a (I²+Q²) signal based on summing of a squared value I² of the I-signal and a squared value Q² of the Q-signal;
first decoding error detection means for detecting a decoding error of decoded data to be decoded by the first decoding means;
second decoding error detection means for detecting a decoding error of decoded data to be decoded by the second decoding means;
third decoding error detection means for detecting a decoding error of decoded data to be decoded by the third decoding means;
first data error detection means for using an error detection code included in decoded data to be decoded by the first decoding means to detect a data error of the decoded data;
second data error detection means for using an error detection code included in decoded data to be decoded by the second decoding means to detect a data error of the decoded data; and
third data error detection means for using an error detection code included in decoded data to be decoded by the third decoding means to detect a data error of the decoded data.

3. The apparatus according to claim 2, wherein the storage means stores decoded data having no decoding error in the detection results of the respective decoding error detection means as normal decoded data under a condition that at least one of the detection results of the respective data error detection means has no data error.

4. The apparatus according to claim 2, wherein the storage means stores decoded data having no decoding error in the detection results of the respective decoding error detection means as normal decoded data under a condition that all the detection results of the respective data error detection means have no data error.

5. The apparatus according to claim 4, wherein, provided that more than one of the detection results of the respective decoding error detection means have no decoding error when the condition is established, the storage means stores as normal decoded data a decoded data which is decoded by a decoding means having the highest priority order determined in advance of the respective decoding means corresponding to the decoded data having no decoding error.

6. The apparatus according to claim 2, wherein, when more than one of the detection results of the respective data error detection means have no data error, the storage means, under a condition that the more than one of the detection results of the respective decoding error detection means have no decoding error and the respective decoded data having no decoding error coincide with one another, stores the coinciding decoded data as the normal decoded data.

7. The apparatus according to claim 1, wherein the decoding/error detection means includes:
third decoding means for decoding a (I²+Q²) signal based on summing of a squared value I² of the I-signal and a squared value Q² of the Q-signal;
third decoding error detection means for detecting a decoding error of decoded data to be decoded by the third decoding means; and
third data error detection means for using an error detection code included in decoded data to be decoded by the third decoding means to detect a data error of the decoded data.

8. The apparatus according to claim 1, wherein, after detecting the decoding error of said each decoded data to be decoded, the decoding/error detection means detects the decoded data error of each decoded data using the error detection code included in said each decoded data to be decoded.

9. The apparatus according to claim 1, wherein the decoding/error detection means includes at least one shift register composed of plural bits, fetches said each decoded data to be decoded into the shift register and provided that a value of a highest order bit of the shift register is the same as a value of a second highest order bit thereof, detects that the decoded data in the shift register has a decoding error.

10. A radio tag communication apparatus comprising:
a receiver which receives a signal transmitted from a radio tag, generates an I-signal from the received signal and a local signal having the same frequency as a carrier of the received signal and generates a Q-signal from the received signal and a signal shifted by 90° in phase from the local signal;
a decoder which decodes a plurality of signals relevance to including the I-signal and Q-signal generated by the receiver;
an error detector which detects a decoding error of each decoded data to be decoded by the decoder and detects a decoded data error of each decoded data using an error detection code included in said each decoded data to be decoded by the decoder; and
a memory which, when no more error than a predetermined level exists in the detection result of the decoding error and the detection result of the decoded data error, stores said each decoded data to be decoded by the decoder as normal decoded data.

11. The apparatus according to claim 10, wherein the decoder includes:
a first decoder which decodes the I-signal;
a second decoder which decodes the Q-signal;
a third decoder which decodes a (I²+Q²) signal based on summing of a squared value I² of the I-signal and a squared value Q² of the Q-signal, and
the error detector includes:
a first decoding error detector which detects a decoding error of decoded data to be decoded by the first decoder;
a second decoding error detector which detects a decoding error of decoded data to be decoded by the second decoder;
a third decoding error detector which detects a decoding error of decoded data to be decoded by the third decoder;
a first data error detector which uses an error detection code included in decoded data to be decoded by the first decoder to detect a data error of the decoded data;
a second data error detector which uses an error detection code included in decoded data to be decoded by the second decoder to detect a data error of the decoded data; and
a third data error detector which uses an error detection code included in decoded data to be decoded by the third decoder to detect a data error of the decoded data.

12. The apparatus according to claim 11, wherein the memory stores decoded data having no decoding error in the detection results of the respective decoding error detectors as normal decoded data under a condition that at least one of the detection results of the respective data error detectors has no data error.

13. The apparatus according to claim 11, wherein the memory stores decoded data having no decoding error in the detection results of the respective decoding error detectors as normal decoded data under a condition that all the detection results of the respective data error detectors have no data error.

14. The apparatus according to claim 13, wherein, provided that if more than one of the detection results of the respective decoding error detectors have no decoding error when the condition is established, the memory stores as normal decoded data a decoded data which is decoded by a decoder having the highest priority order determined in advance of the respective decoders corresponding to the decoded data having no decoding error.

15. The apparatus according to claim 11, wherein, when more than one of the detection results of the respective data error detectors have no data error, the memory, under a condition that the more than one of the detection results of the respective decoding error detectors have no decoding error and the respective decoded data having no decoding error coincide with one another, stores the coinciding decoded data as the normal decoded data.

16. The apparatus according to claim 10, wherein, after detecting the decoding error of said each data decoded by the decoder, the error detector detects the decoded data error of each decoded data using the error detection code included in said each decoded data to be decoded by the decoder.

17. The apparatus according to claim 10, wherein the error detector includes at least one shift register composed of plural bits, fetches decoded data to be decoded by the decoder into the shift register and if values of given successive two bits of the shift register excluding a lowest order bit are identical, detects that the decoded data in the shift register has a decoding error.

18. The apparatus according to claim 17, wherein the given successive two bits excluding the lowest order bit are a highest order bit and a second highest order bit.

19. A radio tag communication apparatus comprising:
receiving means for receiving a signal transmitted from a radio tag, generating an I-signal from the received signal and a local signal having the same frequency as a carrier of the received signal and generating a Q-signal from the received signal and a signal shifted by 90° in phase from the local signal;
decoding/error detection means for decoding a plurality of signals including the I-signal and Q-signal generated by the receiving means, and detecting a decoding error of each decoded data to be detected; and
storage means for, when no more error than a predetermined level exists in the detection result of the decoding error, storing said each decoded data to be detected as normal decoded data.

20. An apparatus according to claim 19, wherein the decoding/error detection means detects a decoded data error of each decoded data using an error detection code included in said each decoded data to be detected.
